(19) United States
(12) Patent Application Publication
(10) Pub. No.: US 2003/0045038 A1
(43) Pub. Date: Mar. 6, 2003

(54) Method of forming low-temperature polysilicon

(76) Inventors: Hsin-Hsien Lin, Taichung (TW); Jam-Wem Lee, Tai-Dong Hsien (TW); Shao-Liang Cheng, Taoyuan (TW); Lih-Juann Chen, Miaoli Hsien (TW); Yuan-Ching Peng, Hsinchu (TW); Wen-Tung Wang, Hsinchu (TW)

Correspondence Address: BIRCH STEWART KOLASCH & BIRCH, PO BOX 747, FALLS CHURCH, VA, 22040-0747, US

(21) Appl. No.: 09/984,311

(22) Filed: Oct. 29, 2001

(30) Foreign Application Priority Data
Aug. 29, 2001 (TW) 90121245

(51) Int. Cl. H01L 21/00; H01L 21/84

(52) U.S. Cl. 438/166; 438/479; 438/466; 438/470

(57) ABSTRACT

A method of forming a low-temperature polysilicon, comprising steps of: providing a substrate with a surface on which a buffer layer, an amorphous silicon layer and a metal silicide layer are sequentially formed; forming a plurality of metal pads on predetermined regions of the metal silicide layer; and providing a current on the metal pads to transform the amorphous silicon layer into a polysilicon layer.

### BACKGROUND OF THE INVENTION

1. Field of the Invention

The present invention relates to a method of forming polysilicon and, more particularly, to a method of forming a low-temperature polysilicon.

2. Description of the Related Art

Thin film transistor (TFT) is used in a variety of integrated circuits, and in particular, as a switching device in each pixel area of liquid crystal display (LCD). According to the materials used, a TFT is classified as an amorphous silicon (a-Si) TFT or a polysilicon TFT. Compared with a-Si TFT, polysilicon TFT has advantages of high carrier mobility, high integration of driving circuits, small leakage current, and higher speed operation, and is often applied to large-size LCDs. In conventional formation of a polysilicon film for TFT, an a-Si film is formed on a glass substrate and then crystallized by heat treatment or excimer laser annealing (ELA). The heat treatment, however, requires a high temperature difficult to apply to a glass substrate, and cannot obtain sufficient crystallinity in the polysilicon film. Conversely, ELA's laser light only illuminates a small area and hence throughput is low. Furthermore, ELA also presents the problem of poorly controlled uniformity of crystal grain size and crystal grain distribution in the polysilicon film.

Seeking to solve the above-described problems, metal induced lateral crystallization (MILC) was developed to add metal elements to the A-Si layer to obtain the polysilicon film through heat treatment conducted at a lower temperature than the conventional method. FIGS. 1A to 1D are sectional diagrams showing the MILC process according to the prior art. As shown in FIG. 1A, a glass substrate 10 has a buffer layer 12 of silicon oxide, an a-Si layer 14 deposited on a predetermined region of the buffer layer 12 by CVD, and a silicon oxide layer 16 formed on the a-Si layer 14. In the MILC process, a nickel silicide (NiSiₓ) layer 18 is sputtered on the entire surface of the glass substrate 10 to cover the sidewall of the a-Si layer 14. Then, using annealing, the a-Si layer 14 is heated at 300˜600° C. for 1 hour to form a nickel silicide region 20 on the sidewall of the a-Si layer 14. As shown in FIG. 1B, after removing the nickel silicide layer 18, the a-Si layer 14 is annealed at 550° C. for 4 hours to grow crystals parallel to the substrate 10 as indicated by the arrows 22. Thus, the a-Si layer 14 is transformed into a polysilicon layer 14″. Thereafter, the nickel silicide region 20 is removed as shown in FIG. 1C, and the silicon oxide layer 16 is then removed as shown in FIG. 1D. The subsequent TFT processes can proceed on the polysilicon layer 14″. The above-described MILC process, however, requires two steps of annealing, in which the high annealing temperature is difficult to apply to a glass substrate, and the long annealing time increases the process complexity and process costs.

### SUMMARY OF THE INVENTION

The present invention is a method of forming low-temperature polysilicon, which uses current induced amorphous silicon recrystallization to solve problems caused by high-temperature and long-term annealing treatment.

The method of forming a low-temperature polysilicon, comprises steps of: providing a substrate with a surface which a buffer layer, an amorphous silicon layer and a metal silicide layer are sequentially formed on; forming a plurality of metal pads on predetermined regions of the metal silicide layer; and providing a current on the metal pads to transform the amorphous silicon layer into a polysilicon layer.

Accordingly, it is a principle object of the invention to use current to induce amorphous silicon recrystallization to form the polysilicon layer.

It is another object of the invention to use low-temperature and short-term annealing.

Yet another object of the invention is to provide a simple and well controlled process to reduce costs.

It is a further object of the invention to be applied to a large-size glass substrate.

These and other objects of the present invention will become readily apparent upon further review of the following specification and drawings.

### BRIEF DESCRIPTION OF THE DRAWINGS

FIGS. 1A to 1D are sectional diagrams showing the MILC process according to the prior art.

FIGS. 2A to 2H are sectional diagrams showing a method of forming a polysilicon layer according to the present invention.

FIG. 3 is a sectional diagram showing another method of forming a polysilicon layer according to the present invention.

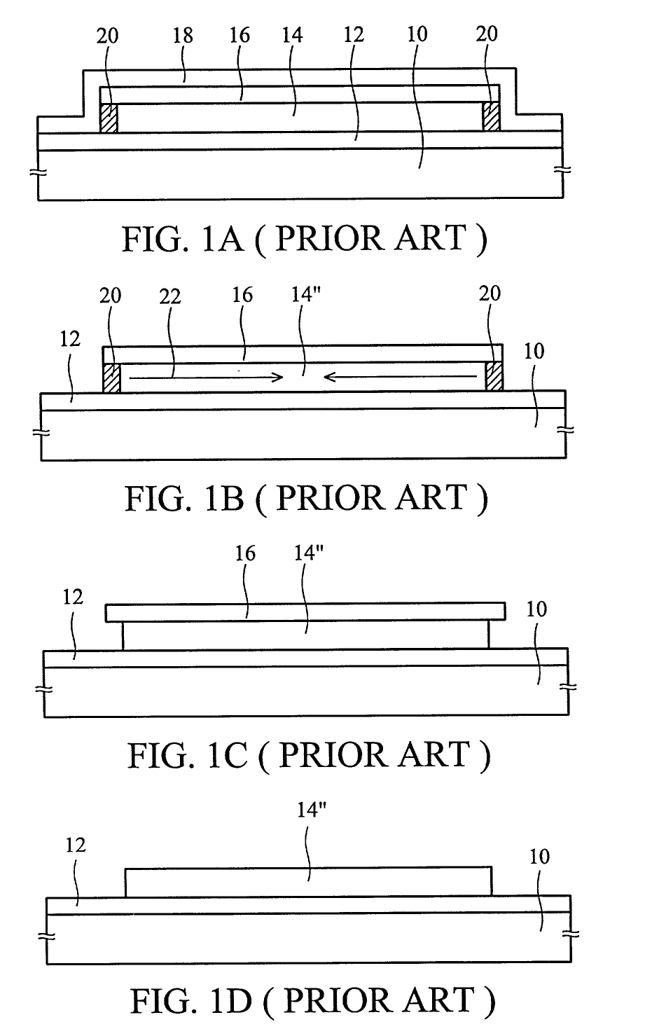

Similar reference characters denote corresponding features consistently throughout the attached drawings.

### DETAILED DESCRIPTION OF THE PREFERRED EMBODIMENTS

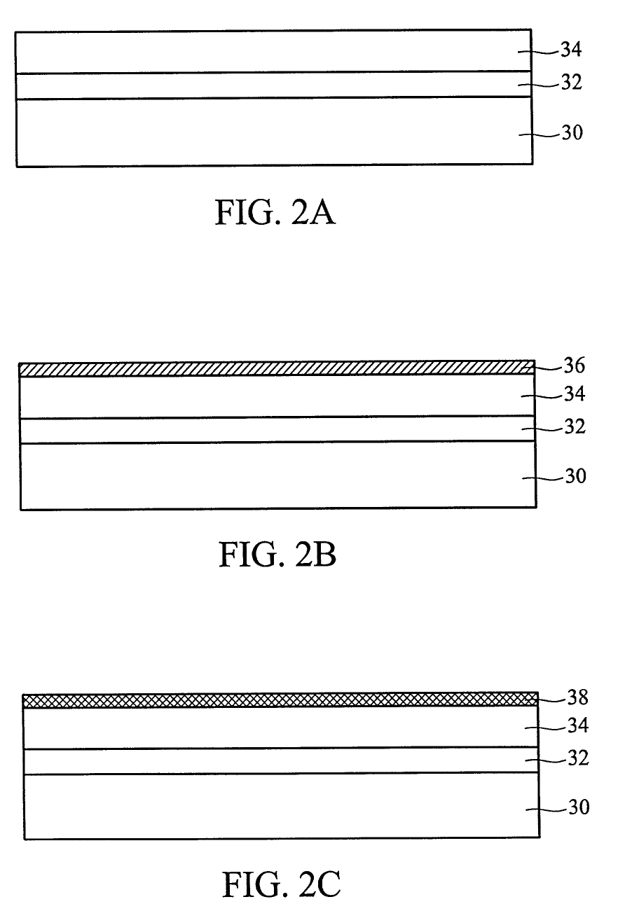

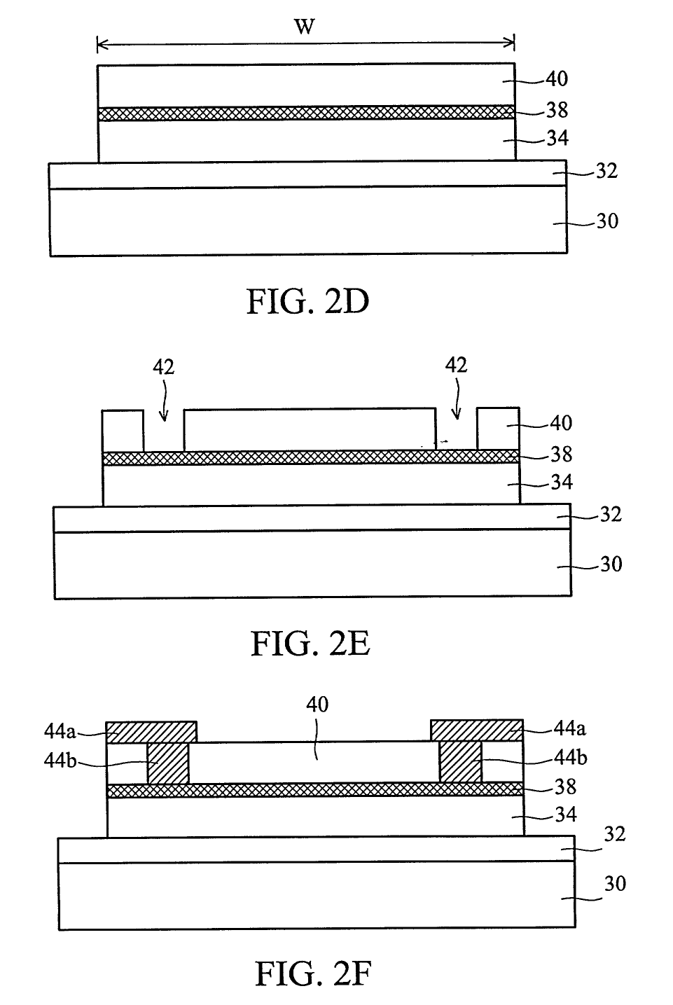

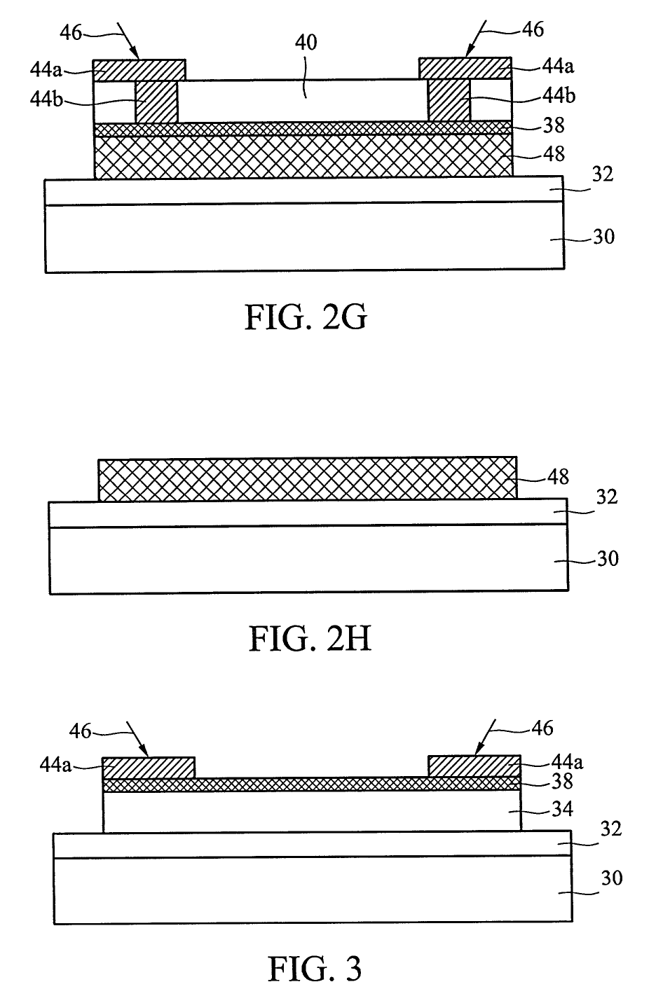

FIGS. 2A to 2H are sectional diagrams showing a method of forming a polysilicon layer by current-induced amorphous silicon recrystallization according to the present invention. As shown in FIG. 2A, a substrate 30 has a buffer layer 32 and an a-Si layer 34. The substrate 30 may be silicon, glass or other transparent insulating materials. The buffer layer 32 may be silicon oxide or silicon nitride. The a-Si layer 34 may be ion-doped amorphous silicon or ion-undoped amorphous silicon. As shown in FIG. 2B, a first metal layer 36 of 40˜80 Å thickness is formed on the a-Si layer 34. The first metal layer 36 may be Ni, Al, Co or Ta. Then, as shown in FIG. 2C, using a low-temperature and short-term annealing treatment, such as RTA, the first metal layer 36 is heated at a temperature lower than 500° C. (preferably at 400˜300° C.) for 1˜3 minutes to form a metal silicide layer 38.

As shown in FIG. 2D, a dielectric layer 40 of silicon oxide or silicon nitride is formed on the metal silicide layer 38. Next, using photolithography and etching, the a-Si layer 34, the metal silicide layer 38 and the dielectric layer 40 are patterned as a strip. Depending on the process requirements, the width, length and profile of the strip pattern are design choices. It is noted that the size of the a-Si layer 34 is related to the value of current provided in subsequent process. Thereafter, as shown in FIG. 2E, using photolithography and etching with a predetermined mask, a plurality of contact holes 42 are formed in the dielectric layer 40 to expose predetermined regions of the metal silicide layer 38. The contact holes 42 are aligned over two sides of the a-Si layer 34, and the number and size of the contact holes 42 are design choices. Next, as shown in FIG. 2F, a second metal layer 44 is formed on the dielectric layer 40 to fill the contact holes 42. The second metal layer 44 may be Ni, Al, Co or Ta. Then, using photolithography and etching to pattern the second metal layer 44, the second metal layer 44 remaining on the dielectric layer 40 serves as a metal pad 44a, and the second metal layer 44 remaining in each contact hole 42 serves as a metal plug 44b. Thus, the metal pad 44a is electrically connected to the metal silicide layer 38 through the metal plug 44b.

As shown in FIG. 2G, the current 46, provided to the metal pads 44a, can induce the a-Si layer 34 to grow crystal grains, resulting in a polysilicon layer 48. It is noted that the degree of current 46 and corresponding voltage depends on the pattern size of the a-Si layer 34. Finally, as shown in FIG. 2H, the metal pads 44a, the metal plugs 44b, the dielectric layer 40 and the metal silicide layer 38 are successively removed, thus the subsequent TFT processes can proceed on the polysilicon layer 48.

In another preferred embodiment, as shown in FIG. 3, the fabrication of the dielectric layer 40 is omitted, and the metal pads 44a can be formed on the metal silicide layer 38. The current 46 can induce the a-Si layer 34 to grow crystal grains, resulting in the polysilicon layer 48.

Compared with the prior MILC method, the present invention uses current 46 to induce amorphous silicon recrystallization to form the polysilicon layer 48. Only one step of low-temperature and short-term annealing treatment is required, hence the process is simple and well controlled to reduce the process costs. Also, the present invention is well applied to a large-size glass substrate.

It is to be understood that the present invention is not limited to the embodiments described above, but encompasses any and all embodiments within the scope of the following claims.

What is claimed is:

1. A method of forming a low-temperature polysilicon, comprising steps of:
providing a substrate with a surface on which a buffer layer, an amorphous silicon layer and a metal silicide layer are sequentially formed;
forming a plurality of metal pads on predetermined regions of the metal silicide layer; and
providing a current on the metal pads to transform the amorphous silicon layer into a polysilicon layer.

2. The method according to claim 1, wherein the method of forming the metal silicide layer comprises steps of:
forming a first metal layer on the amorphous silicon layer; and
annealing the first metal layer to serve as the metal silicide layer.

3. The method according to claim 2, wherein the first metal layer is annealed at 400˜300° C. for 1˜3 minutes.

4. The method according to claim 2, wherein the first metal layer is selected from at least one of the group consisting of Ni, Al, Co and Ta.

5. The method according to claim 1, before the formation of the metal pads, further comprising steps of:
forming a dielectric layer on the metal silicide layer;
forming a plurality of contact holes in the dielectric layer to expose the predetermined regions of the metal silicide layer;
forming a second metal layer on the dielectric layer to fill the contact holes; and
patterning the second metal layer on the dielectric layer as the metal pads, wherein each metal pad is over each contact hole.

6. The method according to claim 5, wherein the dielectric layer is silicon oxide or silicon nitride.

7. The method according to claim 5, wherein the second metal layer is selected from at least one of the group consisting of Ni, Al, Co and Ta.

8. The method according to claim 1, wherein the substrate is selected from one of the group consisting of silicon, glass and transparent insulating materials.

9. The method according to claim 1, wherein the buffer layer is silicon oxide or silicon nitride.

10. The method according to claim 1, wherein the method is applied to liquid crystal display (LCD) process.
